(19) United States
(12) Patent Application Publication
(10) Pub. No.: US 2026/0227439 A1
(43) Pub. Date: Aug. 6, 2026

(54) CONTROLLING TESTABILITY OF A TRUE COMPLEMENT DYNAMIC CIRCUIT

(71) Applicant: International Business Machines Corporation, Armonk, NY (US)

(72) Inventors: Silke Penth, Holzgerlingen (DE); Harry Barowski, Schoenaich (DE); AMIRA ROZENFELD, Rochester, MN (US); Rolf Sautter, Bondorf (DE); Heiko Daniel Fülle, Stuttgart (DE)

(21) Appl. No.: 19/042,476

(22) Filed: Jan. 31, 2025

(51) Int. Cl. G01R 31/3177; H03K 3/037; H03K 19/21

(52) U.S. Cl. CPC G01R 31/3177; H03K 3/037; H03K 19/21

(57) ABSTRACT

A first circuit is configured to perform a Boolean logic, the first circuit configured to receive via bit lines, a first input signal and a second input signal, where the first input signal and the second input signal are dynamic signals that are complementary signals during an evaluation phase. The first circuit is further configured to receive a third input signal and a fourth input signal via data lines. A second circuit is connected to the first circuit and configured to control a logical behavior of the first circuit by controlling at least one of: the third input signal and the fourth input signal, received at the first circuit.

### BACKGROUND

The present application relates generally to computers and circuits, and more particularly to a circuit that can perform multiple different Boolean logic functions and control thereof, and controlling testability of a true complement dynamic circuit.

### BRIEF SUMMARY

The summary of the disclosure is given to aid understanding of controlling testability of a true complement dynamic circuit, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the devices and/or their method of operation to achieve different effects.

In some embodiments, a device is provided that enhances testability of dynamic circuits. The device includes a first circuit configured to perform a Boolean logic, the first circuit configured to receive via bit lines, a first input signal and a second input signal, where the first input signal and the second input signal are dynamic signals that are complementary signals during an evaluation phase, the first circuit further configured to receive a third input signal and a fourth input signal via data lines. The device also includes a second circuit connected to the first circuit and configured to control a logical behavior of the first circuit by controlling at least one of: the third input signal and the fourth input signal, received at the first circuit.

In some embodiments, a method is provided that enhances testability of dynamic circuits. A method includes configuring a first circuit to perform a Boolean logic, the first circuit configured to receive via bit lines, a first input signal and a second input signal, where the first input signal and the second input signal are dynamic signals that are complementary signals during an evaluation phase, the first circuit further configured to receive a third input signal and a fourth input signal via data lines. The method also includes receiving, by a second circuit, an enable test signal as an input to the second circuit. The method further includes, using the enable test signal, controlling, by the second circuit, a logical behavior of the first circuit by controlling the third input signal received at the first circuit.

In some embodiments, a method includes configuring a first circuit to perform a Boolean logic, the first circuit configured to receive via bit lines, a first input signal and a second input signal, where the first input signal and the second input signal are dynamic signals that are complementary signals during an evaluation phase, the first circuit further configured to receive a third input signal and a fourth input signal via data lines. The method also includes receiving, by a second circuit, an enable test signal. The method also includes, using the enable test signal, controlling, by the second circuit, a logical behavior of the first circuit by controlling the fourth input signal received at the first circuit.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 depicts a true complement dynamic circuit that compares binary data, and representing an XNOR gate in some embodiments.

FIG. 2A illustrates a block diagram of a circuit that can perform XNOR function in some embodiments.

FIG. 2B is a block diagram illustrating a circuit that can perform AND function in some embodiments.

FIG. 2C illustrates a block diagram of a circuit that can perform OR function in some embodiments.

FIG. 3A shows a logic gate configuration in some embodiments for providing controllable input to a circuit shown in FIG. 1.

FIG. 3B shows another logic gate configuration in some embodiments for providing controllable input to a circuit shown in FIG. 1.

FIG. 4A shows another example implementation of a logic gate that provides controllable input for switching the operations of a circuit in some embodiments.

FIG. 4B shows yet another implementation of a logic gate that provides controllable input for switching the operations of a circuit in some embodiments.

FIG. 5A shows another example implementation of a logic gate that provides controllable input for switching the operations of a circuit in some embodiments.

FIG. 5B shows still yet another example implementation of a logic gate that provides controllable input for switching the operations of a circuit in some embodiments.

FIG. 6 is a flow diagram illustrating a method of switching a circuit to function as one of a plurality of logical gate functions in some embodiments.

FIG. 7 is a flow diagram illustrating a method of switching circuit functions based on desired operations in some embodiments.

FIG. 8 is another diagram illustrating a method in some embodiments, for flexibly switching a circuit's behavior in some embodiments.

FIG. 9 is yet another diagram illustrating a method in some embodiments, for flexibly switching a circuit's behavior in some embodiments.

### DETAILED DESCRIPTION

A method is provided that enhances testability of dynamic circuits in some embodiments. The method in some embodiments enhances or improves testability of a true complement dynamic circuit. A method includes configuring a first circuit to perform a Boolean logic, the first circuit configured to receive via bit lines, a first input signal and a second input signal, where the first input signal and the second input signal are dynamic signals that are complementary signals during an evaluation phase, the first circuit further configured to receive a third input signal and a fourth input signal via data lines. The method also includes receiving, by a second circuit, an enable test signal as an input to the second circuit. The method further includes, using the enable test signal, controlling, by the second circuit, a logical behavior of the first circuit by controlling the third input signal received at the first circuit.

The method provides for flexible capability to switch functions of the first circuit. For example, the second circuit functions as a switch to control the functions of the first circuit by controlling of the input signals, here the third input signal, received at the first circuit.

One or more of the following features can be separable or optional from each other.

The method also includes, responsive to the enable test signal being set to enabled, outputting by the second circuit, inverted compare data as the third input signal that is received by the first circuit, where the inverted compare data as the third input signal received by the first circuit causes the first circuit to perform an XNOR logic, where the third input signal and the fourth input signal received by the first circuit are complementary signals. Thus, for example, the method allows for switching the function of the first circuit to enable full testability of the first circuit by controlling the input data received as the third input signal.

The method also includes, responsive to the enable test signal being deactivated, outputting by the second circuit, a value of zero as the third input signal that is received by the first circuit, where the zero value as the third input signal received by the first circuit causes the first circuit to perform an AND logic. In this way, the method, based on test enable signal (e.g., enable test signal) being not set or deactivated, allows for flexibly switching the first circuit to AND function, e.g., perform an AND logic, or e.g., behave as an AND gate.

In some embodiments, the second circuit is configured with an AND gate. This AND gate receives as input the enable test signal and an inverted value of compare data, where an output of the AND gate is fed as the third input signal to the first circuit (e.g., via the complement compare data line). This AND gate allows for logically combining its inputs such that the output of the AND gate fed to the first circuit controls the functional modes of the first circuit.

In some embodiments, the method also includes multiplexing by a multiplexer configured on the second circuit, based on the enable test signal as a selector input of the multiplexer, signals between a control signal from an external engine external to the second circuit and ground level voltage. The method further includes using, by the second circuit, output of the multiplexer to control the logical behavior of the first circuit. In this way, an external engine can further control the logical behavior or function of the first circuit.

In some embodiments, the method also includes receiving by a latch configured on the second circuit, a control signal from an external engine external to the second circuit and ground level voltage. The method also includes using, by the second circuit, output of the latch to control the logical behavior of the first circuit. Using a latch configuration in the second circuit can resolve potential timing conflicts such as race conditions.

In some embodiments, a method includes configuring a first circuit to perform a Boolean logic, the first circuit configured to receive via bit lines, a first input signal and a second input signal, where the first input signal and the second input signal are dynamic signals that are complementary signals during an evaluation phase, the first circuit further configured to receive a third input signal and a fourth input signal via data lines. The method also includes receiving, by a second circuit, an enable test signal. The method also includes, using the enable test signal, controlling, by the second circuit, a logical behavior of the first circuit by controlling the fourth input signal received at the first circuit.

In this way, the method provides for flexible capability to switch functions of the first circuit. For example, the second circuit functions or operates as a switch to control the functions of the first circuit by controlling of the input signals, here the fourth input signal, received at the first circuit.

One or more of the following features can be separable or optional from each other.

In some embodiments, the method also includes, responsive to the enable test signal being set to enabled, outputting by the second circuit, compare data as the fourth input signal received by the first circuit, where the compare data as the fourth input signal received by the first circuit causes the first circuit to perform an XNOR logic, where the third input signal and the fourth input signal received by the first circuit are complementary signals. Thus, for example, the method allows for switching the function of the first circuit to enable full testability of the first circuit by controlling the input data received as the fourth input signal.

In some embodiments, the method also includes, responsive to the enable test signal being deactivated, outputting by the second circuit, a value of one as the fourth input signal received by the first circuit, where the value of one as the fourth input signal received by the first circuit causes the first circuit to perform an OR logic. In this way, the second circuit controls the first circuit to perform a function of an OR gate.

In some embodiments, the second circuit is configured with an OR gate. This OR gate receives as input an inverted value of the enable array built-in self-test signal and compare data, where an output of the OR gate is fed as the fourth input signal to the first circuit. Using such logical OR gate, the second circuit controls its output, which is fed to the first circuit to control the logical behavior of the first circuit.

In some embodiments, a device is provided that enhances testability of dynamic circuits. The device includes a first circuit configured to perform a Boolean logic, the first circuit configured to receive via bit lines, a first input signal and a second input signal, where the first input signal and the second input signal are dynamic signals and are complementary signals during an evaluation phase, the first circuit further configured to receive a third input signal and a fourth input signal via data lines. The device also includes a second circuit connected to the first circuit and configured to control a logical behavior of the first circuit by controlling at least one of: the third input signal and the fourth input signal, received at the first circuit.

Technically, the device provides for flexible capability to switch functions of the first circuit. For example, the second circuit functions or operates as a switch to control the functions of the first circuit by controlling of the input signals, here the third input signal, received at the first circuit.

One or more of the following features can be separable or optional from each other.

In some embodiments, the second circuit is configured to control the logical behavior of the first circuit based on receiving an enable test signal as an input to a logic gate of the second circuit to enable full testability of the first circuit. For example, a second circuit can switch the function of the first circuit that restores full testability of the first circuit from being used in system data mode.

In some embodiments, the enable test signal being enabled causes the second circuit to output inverted compare data as the third input signal that is received by the first circuit, where the inverted compare data as the third input signal received by the first circuit causes the first circuit to perform an XNOR logic, where the third input signal and the fourth input signal received by the first circuit are complementary signals. Thus, for example, the device allows for switching the function of the first circuit to enable full testability of the first circuit by controlling the input data received as the third input signal.

In some embodiments, the enable test signal being deactivated causes the second circuit to output a value of zero as the third input signal that is received by the first circuit, where the zero value as the third input signal received by the first circuit causes the first circuit to perform an AND logic. In this way, the device, based on test enable signal (e.g., enable test signal) being not set or deactivated, allows for flexibly switching the first circuit to AND function, e.g., perform an AND logic, or e.g., behave as an AND gate.

In some embodiments, the enable test signal being enabled causes the second circuit to output compare data as the fourth input signal received by the first circuit, where the compare data as the fourth input signal received by the first circuit causes the first circuit to perform an XNOR logic. Thus, for example, the method allows for switching the function of the first circuit to enable full testability of the first circuit by controlling the input data received as the fourth input signal.

In some embodiments, the enable test signal being deactivated causes the second circuit to output a value of one as the fourth input signal received by the first circuit, where the value of one as the fourth input signal received by the first circuit causes the first circuit to perform an OR logic. In this way, the second circuit controls the first circuit to perform a function of an OR gate.

In some embodiments, the second circuit includes an AND gate configured to receive as input the enable test signal and an inverted value of compare data, where an output of the AND gate is fed as the third input signal to the first circuit. This AND gate allows for logically combining its inputs such that the output of the AND gate fed to the first circuit controls the functional modes of the first circuit.

In some embodiments, the second circuit includes an OR gate configured to receive as input an inverted value of the enable array built-in self-test signal and compare data, where an output of the OR gate is fed as the fourth input signal to the first circuit. Using such logical OR gate, the second circuit controls its output, which is fed to the first circuit to control the logical behavior of the first circuit.

In some embodiments, the second circuit is further configured with a multiplexer that multiplexes between a control signal from an external engine external to the second circuit and ground level voltage, and generates output based on the enable test signal as a selector input of the multiplexer, the second circuit using the output of the multiplexer to control the logical behavior of the first circuit. In this way, an external engine can further control the logical behavior or function of the first circuit.

In some embodiments, the second circuit is further configured with a latch receiving as input a control signal from an external engine external to the second circuit and ground level voltage, the second circuit using output of the latch to control the logical behavior of the first circuit. Using a latch configuration in the second circuit can resolve potential timing conflicts such as race conditions.

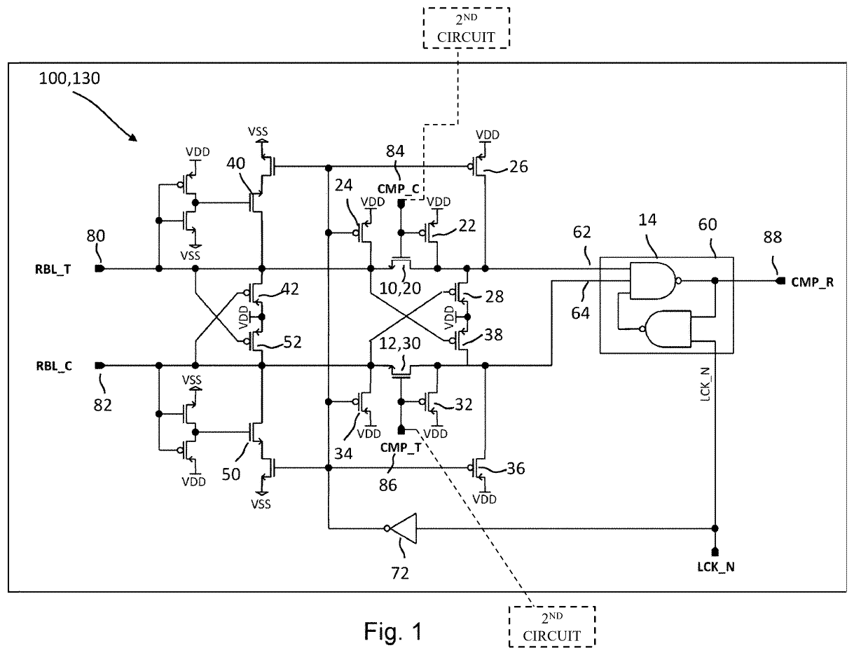

FIG. 1 depicts an example of true complement dynamic circuit 100 in some embodiments. As described in more detail below, circuit 100 (also referred to as first circuit) can be configured to perform different logical functions. In some embodiments, circuit 100 is used for combining, for example, comparing, binary data on dynamic first and second input signals 80, 82 to third and fourth input signals 84, 86 representing an XNOR gate as a precharge to ‘1’ logic circuit in some embodiments. In some embodiments, the circuit 100 uses dual rail dynamic circuitry in combination with pass gate devices to resemble a logic gate. A dynamic to static conversion is done via a clocked cross coupled NAND gate. Bit lines and data lines refer to wires in a circuit that can receive signals, such as input signals.

In some embodiments, circuit 100 is a dual rail dynamic circuit. For example, dynamic circuits use a wire which is precharged (like a capacitor, e.g., to VDD, i.e., the logic state ‘1’) in a first precharge phase, which may be the first half of a clock cycle. In a second (e.g., evaluation) phase a (static) input may stimulate a single transistor to discharge the wire to achieve a logic 0 state. Since the circuit only acts fast on the 1->0 transition, one can use the circuit on the opposite polarity (complement signal) in parallel to also cope with the 0->1 transition in a logical representation with the complementary signal line. In some embodiments, techniques disclosed herein allow to establish and re-establish full test capabilities to the dual rail dynamic signal lines. For example, a second circuit can be connected to circuit 100 (first circuit) to control the logical behavior of circuit 100 (first circuit).

The following reference numerals are used in FIG. 1: 10—first part; 12−second part; 14—third part; 20—pass gate transistor; 22—keeper device; 24—precharging device; 26—precharging device; 28—keeper device; 30—pass gate transistor; 32—keeper device; 34—precharging device; 36—precharging device; 38—keeper device; 40—keeper device; 42—keeper device; 50—keeper device; 52—keeper device; 60—logical component; 62—fifth signal; 64—sixth signal; 72—inverter; 80—first input signal; 82—second input signal; 84—third input signal; 86—fourth input signal; 88—seventh signal, output signal; 100—true complement dynamic circuit; 130—1-bit compare circuit.

The following notations are used with reference to FIG. 1. CMP_T: true compare data line; CMP_C: complement compare data line; RBL_T: true read bit line; RBL_C: complement read bit line; CMP_R: output; LCK_N: negative active logical clock; VDD: power supply voltage; VSS: ground level voltage.

The true complement dynamic circuit 100 is configured as a 1-bit compare circuit 130, where the dynamic first and second input signals 80, 82 are complementary signals during an evaluation phase. The logical behavior is determined by the third and fourth input signals 84, 86, where the third and fourth input signals 84, 86 are dynamic or static signals.

The first and second input signals 80, 82 are received from a true read bit line RBL_T and a complement read bit line RBL_C, respectively, where both signals 80, 82 are dynamic input signals. The true read bit line RBL_T and a complement read bit line RBL_C, e.g., may be received from a memory cell as an SRAM cell.

The logical behavior represents an XNOR gate, if the third and fourth input signals 84, 86 are complementary signals during an evaluation phase. The third input signal 84 is received from a complement compare data line CMP_C and the fourth input signal 86 is received from a true compare data line CMP_T. Both signals 84, 86, e.g., typically come from logic functions, in particular may be received from a memory cell as an SRAM cell.

The 1-bit compare circuit 130 comprises a first part 10 which is logically combining the first input signal 80 and the third input signal 84 with a logical ‘A OR NOT B’ operation creating a fifth signal 62. Further it comprises a second part 12 which is logically combining the second input signal 82 and the fourth 86 input signal with a logical ‘A OR NOT B’ operation creating a sixth signal 64. Further it comprises a third part 14 for logically combining the fifth signal 62 and the sixth signal 64 to a seventh signal 88 as an output CMP_R.

The first part 10 includes a first pass gate transistor 20, where the first input signal 80 is received on a source of the first pass gate transistor 20; and where the third input signal 84 is received on a gate of the first pass gate transistor 20.

The second part 12 includes a second pass gate transistor 30, where the second input signal 82 is received on a source of the second pass gate transistor 30; and where the fourth input signal 86 is received on a gate of the second pass gate transistor 30.

The third part 14 includes a logical component 60, where the fifth signal 62 is received on a first input of the logical component 60; and where the sixth signal 64 is received on a second input of the logical component 60. The logical component 60 is implemented as a cross-coupled two-way NAND gate and represents a prefetch latch converting dynamic input signals 80, 82 back to a static output signal 88.

The seventh signal 88 is a comparison result of the first input signal 80 and the second input signal 82 versus the third input signal 84 and the fourth input signal 86, respectively, as an output CMP_R.

The first input signal 80 and the second input signal 82 are dynamic signals, in particular restored to ‘1’ signals during a precharge phase and complementary signals during an evaluation phase. The third input signal 84 and the fourth input signal 86 are static signals or dynamic signals. For compare operations the third input signal 84 and the fourth input signal 86 are complementary signals.

The true complement dynamic circuit 100 is controlled by a negative active clock signal LCK_N, which is directly received as an input by the third part 14 and which is received as an input by the first part 10 and the second part 12 via an inverter 72.

P-channel field-effect transistor (PFET) devices 24, 34 are used for precharging the first input signal 80 and the second input signal 82 to ‘1’.

Cross-coupled transistors 42, 52 are implemented for preserving precharge levels of the first input signal 80 or the second input signal 82, in particular only for the one of both input signals 80, 82 that is not pulled down by an SRAM cell or an evaluation device (like an NFET). The true complement dynamic circuit 100 comprises N-keeper devices 40, 50 gated by the inverted negative active clock signal LCK_N and controlled by the inverted input signals 80, 82.

The third input signal 84 is connected to the gate of a keeper device 22 as a keeper for the fifth signal 62 and the fourth input signal 86 is connected to the gate of a keeper device 32 as a keeper for the sixth signal 64.

In some embodiments PFET devices 26, 36 are used for precharging the fifth signal 62 and the sixth signal 64. Voltage at the drain (VDD) represents the power supply voltage, Voltage at the source (VSS) represents the respective ground level voltage.

The circuit 100 shown in FIG. 1 resembles an XNOR gate if the first and second input signals 80, 82 (RBL_T/RBL_C) and the third and fourth input signals 84, 86 (CMP_T/CMP_C) each represent complementary inputs. Then the pass gate devices 20, 30 with the third and the fourth signal 84, 86 (CMP_T/CMP_C) are logically equivalent to an OR gate. The combination with the NAND gate of the logical component 60, where cross coupled feedback allows for stable static output, represents the logic exclusive NOR function which is a typical 1-bit compare circuit 130.

If the requirement that the third and the fourth signal 84, 86 (CMP_C/CMP_T) are complementary inputs is dropped and either one of the third and the fourth signal 84, 86 (CMP_C/CMP_T) is tied to ‘0’ or ‘1’ other logic functions than XNOR can be achieved.

If the third input signal 84 (CMP_C) is tied to ‘0’ the logical function ‘A AND B’ may result as an output CMP_R of the logical component 60.

If the fourth input signal 86 (CMP_T) is tied to ‘1’ the logical function ‘A OR NOT B’may result as an output CMP_R of the logical component 60.

As described above, circuit 100 has four inputs (first and second inputs 80, 82 as complementary dynamic input lines-the read bit line true and read bit line complement, which for example can be from a memory array cell, and the third and fourth inputs 84, 86 as a complementary part of compare data). In some embodiments, controlling the compare data signals (third and fourth inputs 84, 86) by providing a defined input value, results in a different overall logic function of the first circuit. For instance, controlling the CMP_C 84 or CMP_T 86 input signal can change the function of the circuit 100 as comparator (XNOR) to an AND or OR gate, respectively.

First, second, third, fourth inputs are also referred to as first, second, third, fourth input signals, respectively; first, second, third, fourth signals are referred to as first, second, third, fourth input signals, respectively. Compare data can be any data value, e.g., used in comparison, e.g., by the first circuit.

Boolean logic is also referred to as logic; for example, the terms XNOR Boolean logic is also referred to as XNOR logic, AND Boolean logic is also referred to as AND logic, OR Boolean logic is also referred to as OR logic.

Therefore, logic function of the circuit can be exchanged between XNOR and AND/OR functionality. In some instances, however, a hard tying of bit lines of the circuit to specific bit values may cause latches to capture different values then desired during operation. In addition, such hard tying can result in some input values being unobservable, and difficult to detect during tests. For example, using the circuit for combining logic data with true complement dynamic read data from an array can challenge testability of the array data when using the circuit for implementing AND/OR functionality. For example, when complement compare data line (CMP_C) is tied to one (‘1’), read bit line (RBL_T) cannot be observed. Moreover, special array built in self-test (ABIST) pattern may be needed to account for the logic functionality of the gate. Briefly, ABIST is a self-test technique built into or embedded into a chip or integrated circuit that can be activated to test the integrated circuit for various types of faults and malfunctions.

The signals RBL_T 80 and RBL_C 82 are dynamic signals lines. By way of example, signals RBL_T 80 and RBL_C 82 output the data from a memory array such as an SRAM array. An RBL or read bit line is a dynamic signal line which gets precharged in, for example, a first half of the cycle (precharge phase) and evaluated based on the content of the memory array's cell during the evaluation phase. Dependent on the content of the memory array's cell, RBL_T 80 will show the true value of the memory cell, RBL_C 82 the complementary value. In some embodiments, an array built-in self-test (ABIST) tests every memory cell of the memory array. This implies that the state of the memory cell (0 or 1) should be readable by either the true and the complement bit line. The circuit shown at 100 passes RBL_T 80 and RBL_C 82 to the cross coupled NAND circuit 60 dependent on whether the passgate transistors 10, 20 or 12, 30 are “transparent” so as to pass through the state of RBL_T 80 or RBL_C 82. If circuit 100 is restricted to operate as AND or OR gate, either one of the passgate transistors are switched off - therefore, there is no observation possible to either RBL_T 80 or RBL_C 82. In some embodiments, an extension of the inputs CMP_C 84 or CMP_T 86 added so that in test mode the passgate transistors can be set into transparent mode again to recover observability of RBL_T 80 and RBL_C 82. In some embodiments, techniques disclosed herein allows circuit 100 to re-establish full test capabilities to the dual rail dynamic signal lines.

In some embodiments, an additional circuit is provided that implements switching between XNOR functionality during test enabled setting (test_ena=1), e.g., during ABIST, using test_enable signal and AND/OR functionality. In some additional embodiments, the additional circuit includes components to make the circuit controllable by an external engine such as an ABIST engine, e.g., using another signal, e.g., test_mode signal. In some other embodiments, the additional circuit uses a functional latch input for functional mode and scan latch input for test_enable (and scan) mode.

Systems, methods, and/or techniques disclosed herein improves testability of the logic circuit by switching between AND/OR function and “basic XNOR function” of the circuit. This allows testability of both bitlines and usage of same test algorithm for all bits, independent of the system function. In this way, improved test coverage can be provided, and reduce ABIST algorithm overhead.

A circuit (also referred to as a first circuit) 100 is configured to perform logical gate functions, XNOR, AND and OR, and can be used for reading out from a memory array, where there are read bit line true 80 and read bit line complement 82 for reading complementary data from a device such as Static Random Access Memory (SRAM) cell or register file cell. The read bit line true 80 is a dynamic bit line and the circuit performs dynamic to static conversion. In general, the static conversion for the read bit line true via the circuit is also valid for the inverted read bit line complement 82. The circuit is configured to perform an XNOR function, and can be used to compare memory array data to compare data received externally of the circuit.

Input to the circuit is an array content (e.g., memory array content) 80, 82 and compare data 84, 86. Compare data 84, 86 can be desired or given data used for comparison. Complement compare data 84 is an inverted or complementary value of given compare data, referred to as true compare data or compare true data 84. The circuit performs a logical XNOR between the read bit line 80 to true compare data 86, using complementary data as well 82, 84 to implement the XNOR functionality of the circuit.

In some embodiments, the circuit can also be used for performing additional logic. For example, if the complement compare data line 84 is tied to zero, the circuit acts as an AND gate, i.e., performs logical AND function. If the true compare data line 86 is tied to one, the circuit acts an OR gate, i.e., performs logical OR function.

In the following description, the terms true compare data line and compare true bit line are used interchangeably, an example of which is shown at 84 in FIG. 1; the terms complement compare data line and compare complement bit line are used interchangeably, an example of which is shown at 86 in FIG. 1.

The circuit, also referred to as compare circuitry, uses a combination of passgate devices in combination with a cross coupled NAND 60 and uses true/complement read bit lines 80, 82 with a true/complement compare input 86, 84. By either setting the true compare (CMP_T) data line 86 or complement compare (CMP_C) data line 84 to one or zero, the XNOR circuit behaves as an OR or AND gate. Hard tying of the values allows for only one leg of the circuit to be used, either the true or the complement bit line. To test the memory array cells with respect to the true and complement output, i.e., bit line, the circuit should be restored to perform the XNOR function. In test mode thus, the circuit should remove the tie of either true compare (CMP_T) data line 86 or complement compare (CMP_C) data line 84 input.

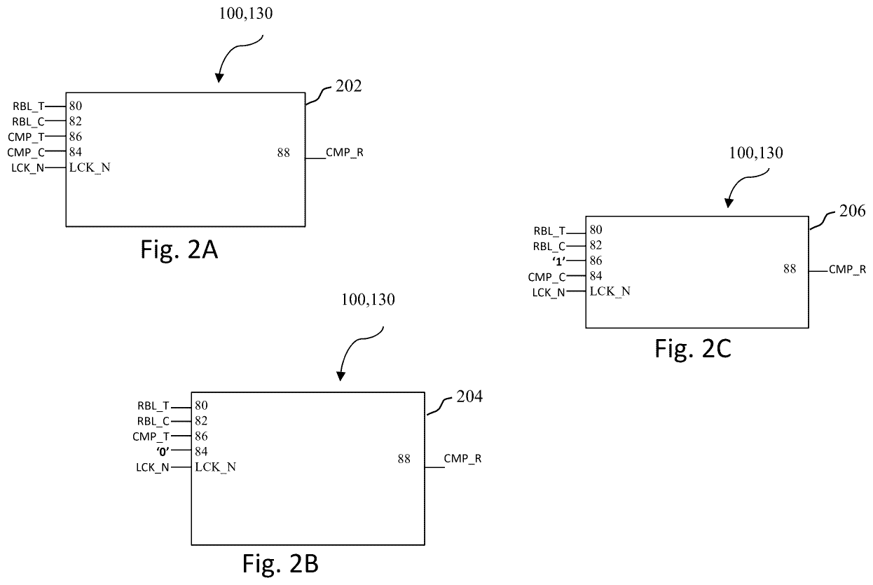

FIG. 2A illustrates a block diagram of a circuit that can perform XNOR function in some embodiments. The block 202 implements the circuit shown in FIG. 1 (or variations thereof) in some embodiments, and includes input lines, true read bit line (RBL_T) 80, complement read bit line (RBL_C) 82, true compare data line (CMP_T) 86, complement compare data line (CMP_C) 84, and clock (negative active clock signal, LCK_N). The output (CMP_R) 88 of the block 202 is logical XNOR of the inputs, e.g., memory array cell data and compare data. In some embodiments, the compare data is an external input to this circuitry. For example, since circuit 100 (e.g., block 302) can represent an XNOR logic gate, in this logical function mode, one may apply a single bit value as a true/complement signal pair and compare it to the value of a memory cell which is read via the dual rail RBL_T and RBL_C. This compare can be an XNOR function.

FIG. 2B is a block diagram illustrating a circuit that can perform AND function in some embodiments. The block 204 implements the circuit shown in FIG. 1 (or variations thereof) in some embodiments, and includes input lines, true read bit line (RBL_T) 80, complement read bit line (RBL_C) 82, true compare data line (CMP_T) 86, complement compare data line (CMP_C) 84, and clock (LCK_N). The output of the block 302 is logical AND of the inputs. The input data value to complement compare data line (CMP_C) 84 is a zero, which drives the circuit to function as an AND gate. As shown, the circuit at complement compare data line (CMP_C) 84 is receiving a zero value. In this configuration, complement compare data line (CMP_T) 86 is connected to cmp_data or compare data. In some embodiments, the compare data is an external input to this circuitry.

FIG. 2C illustrates a block diagram of a circuit that can perform OR function in some embodiments. The block 206 implements the circuit shown in FIG. 1 (or variations thereof) in some embodiments, and includes input lines, true read bit line (RBL_T) 80, complement read bit line (RBL_C) 82, true compare data line (CMP_T) 86, complement compare data line (CMP_C) 84, and clock (LCK_N). The output (CMP_R) 88 of the block 206 is logical OR of the inputs. The input data value to true compare data line (CMP_T) 86 is one, which drives the circuit to function as an OR gate. As shown, the circuit with its true compare data line (CMP_T) 86 receives a one value. In this configuration, complement compare data line (CMP_C) 84 is connected to cmp_data_n. “cmp_data_n” represents an inverted value or complement of “cmp_data” (compare data). In some embodiments, the compare data or inverted compare data is an external input to this circuitry.

In some embodiments, inputs RBL_T and RBL_C are precharged to ‘1’ during precharge phase (when LCK_N=1) and are set to be complementary with respect to each other during evaluation phase. CMP_C and CMP_T are also set to be complementary signals with respect to each other during evaluation phase.

Compare data complement and compare data true are inputs to the circuit (e.g., 202, 204, 206). In some embodiments, a logic gate (also referred to as a second circuit) is provided which can act as a switch or control device for allowing flexibility of switching the functionalities of the circuit. The logic gate, depending on whether the circuit is running on test mode or functional mode, applies a “tie” value and thus configures the compare circuit to an AND or OR function in functional mode, or restores the XNOR circuit in test mode. For instance, instead of using a hard tie at the input of the circuit, the logic gate provides a flexibility to control the behavior of the circuit. For example, the logic gate controls the bit values at complement compare data line (CMP_C) 84 and true compare data line (CMP_T) 86. Thus, the logic gate provides controllable input to the circuit, for driving the circuit's functionality, e.g., among XNOR, AND and OR functions.

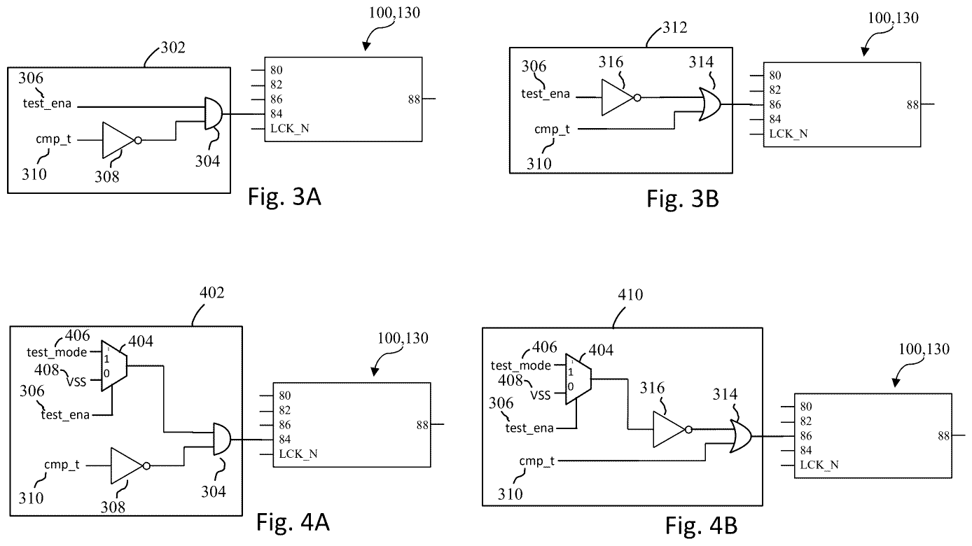

FIGS. 3A, 3B, 4A, 4B, 5A, 5B illustrate examples of circuit topology, which can be used for switching the logic function of the true complement dynamic circuit in some embodiments. The circuitry in the figures show a signal (test_ena), which enables testing, e.g., removing tied input values to inputs 86 or 84 to restore testability of both dual rail dynamic input signal (lines). If testing is not enabled, 86 is logically driven high, so that the circuit acts like an OR gate. In another implementation, e.g., a second implementation, 84 gets logically driven to a 0, causing the circuit to behave as a AND gate.

FIG. 3A shows a logic gate configuration in some embodiments for providing controllable input to a circuit shown in FIG. 1. The logic gate configuration 302 (also referred to as second circuit) acts as a switch to the circuit (e.g., 100, 130, also referred to as first circuit). An AND gate 304 has input connections of an enable bit (test_ena) 306 and inverted compare data bit. The inverted compare data bit is an output of an inverter 308, that receives compare data bit 310. The output of the AND gate 304 connects to complement compare data line (CMP_C) 84 of the circuit 100, 130. The AND gate's output value when zero activates or drives the circuit 100, 130 to act or function as an AND gate. In some embodiments, the enable bit 360 being set to one (e.g., enabled) enables testing, which causes the circuit 100, 130 to behave as an XNOR logic gate (e.g., perform XNOR function). In a different functional operation, e.g., in which the circuit 100, 130 is used as an AND or OR logic gates, the enable bit 306 is set to zero (or deactivated). Setting the enable bit 306 to zero results in the AND gate 304 outputting a zero (independent of the value of the compare data bit 310), which then is received at complement compare data line (CMP_C) 84 of the circuit 100, 130. Zero input to the complement compare data line (CMP_C) 84 of the circuit 100, 130 configures the circuit to operate as an AND Boolean logic gate (e.g., perform AND logic or function).

FIG. 3B shows another logic gate configuration in some embodiments for providing controllable input to a circuit shown in FIG. 1. The logic gate configuration 312 includes an OR gate 314 that has input connections of an inverted enable bit, which is an output of an inverter 316 that receives and inverts an enable bit (test_ena) 306, (test_ena) and compare data bit 310. The output of the OR gate 314 connects to true compare data line (CMP_T) 86 of the circuit 100, 130. The OR gate's output value when set to one, drives the circuit 100, 130 to act or function as an OR gate, e.g., perform an OR Boolean logic. For example, setting the enable bit 306 to zero (deactivating test enable) results in the OR gate 314 outputting a one (e.g., a zero that is inverted is OR'ed with compare data, which results in one), which then is received at true compare data line (CMP_T) 86 of the circuit 100, 130. An input value of one to true compare data line (CMP_T) 86 of the circuit configures the circuit 100,130 to operate as an OR gate (e.g., perform OR Boolean logic or function). Setting the enable bit (test_ena) to one (or enable) causes the circuit 100, 130 to behave as an XNOR logic gate (e.g., perform XNOR Boolean logic).

FIG. 4A shows another implementation of a logic gate that provides controllable input for switching the operations of a circuit in some embodiments. An additional test mode signal is introduced which allows that the test can be enabled for testing the circuit acting as an AND or OR gate, as well as the circuit is acting as XNOR gate where both dual rail dynamic input signals can be tested. In this logic gate configuration or circuit 402, another engine can further control the input. For example, a multiplexer circuit 404 combines an enable bit 306 with another signal or input (referred to as test mode) 406. When enable bit or signal (test_ena) 306 is set to one (enabled), depending on the test mode signal 406, the circuit 100, 130 switches between operating as an AND logic gate and an XNOR logical gate. The terms enable bit and enable signal are used interchangeably herein.

In the logic gate configuration shown in FIG. 4A, the components operate in the same manner as described with reference to FIG. 3A. In this configuration, the enable bit (test_ena) 306 rather than being a direct input to the AND 304 gate as shown in FIG. 3A, the enable bit (test_ena) 306 is connected to a multiplexer circuit 404 as a selector input to the multiplexer circuit 404 that selects between ground level voltage (voltage at source (VSS)) 408 and a signal (test_mode) 406 from a test engine. The test-mode signal 406 from a test engine is a control signal from an external engine that is external to the circuit 402. Output of this multiplexer circuit 404 is then input to the AND gate 304. The AND gate 304 behaves in a similar manner as described with reference to FIG. 3A. enable bit (test_ena) 306 being set to one selects the value of test_mode signal 406; enable bit (test_ena) 306 being set to zero selects the value VSS 408 as the output value of the multiplexer circuit 404. In this way, an external engine (such as array built in self-test (ABIST) engine) may operate to switch the circuit between different logic functions (e.g., XNOR, AND) of the circuit 100, 130.

FIG. 4B shows another implementation of a logic gate that provides controllable input for switching the operations of a circuit in some embodiments. Similar to FIG. 4A, an additional test mode signal is introduced which allows that the test can be enabled for testing the circuit acting as an AND or OR gate, as well as the circuit is acting as XNOR gate where both dual rail dynamic input signals can be tested. In this logic gate configuration 410, another engine can further control the input. For example, a multiplexer circuit 404 combines an enable bit 306 with another signal or input (referred to as test_mode) 406. When enable bit or signal (test_ena) 306 is set to one (enabled), depending on the test_mode signal 406, the circuit 100, 130 switches between operating as an OR logic gate and an XNOR logical gate. The terms enable bit and enable signal are used interchangeably herein.

In the logic gate configuration shown in FIG. 4B, the components operate in the same manner as described with reference to FIG. 3B. In this configuration, the enable bit (test_ena) 306 rather than being a direct input to the inverter 316 as shown in FIG. 3B, the enable bit (test_ena) 306 is connected to a multiplexer circuit 404 as a selector input to the multiplexer circuit 404 that selects between ground level voltage (voltage at source (VSS)) 408 and a signal (test_mode) 406 from a test engine. The test_mode signal 406 from a test engine is a control signal from an external engine that is external to the circuit 410. Output of this multiplexer circuit 404 is then input to the inverter 316. The OR gate 314 behaves in a similar manner as described with reference to FIG. 3B. Enable bit (test_ena) 306 being set to one selects the value of test_mode 406; enable bit (test_ena) 306 being set to zero selects the value VSS 408 as the output value of the multiplexer circuit 404. In this way, an external engine (such as array built in self-test (ABIST) engine) may operate to switch the circuit between different logic functions (e.g., XNOR, OR) of the circuit 100, 130.

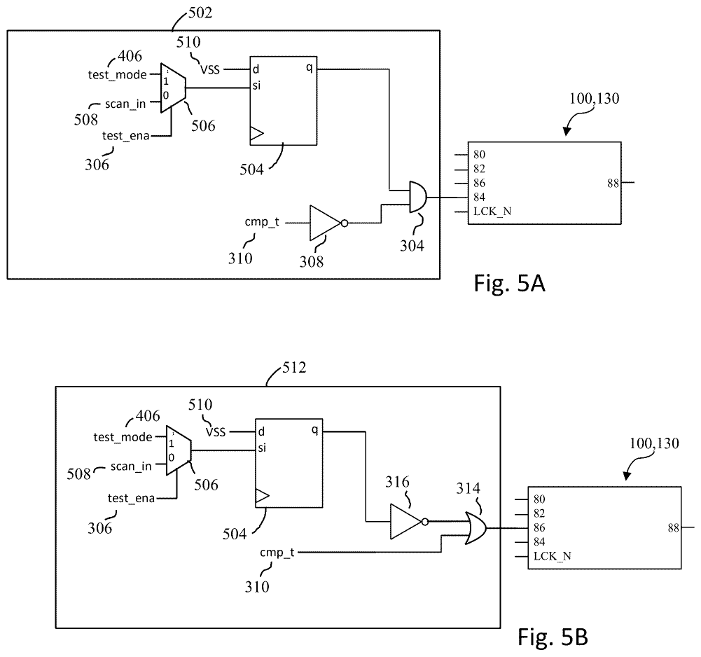

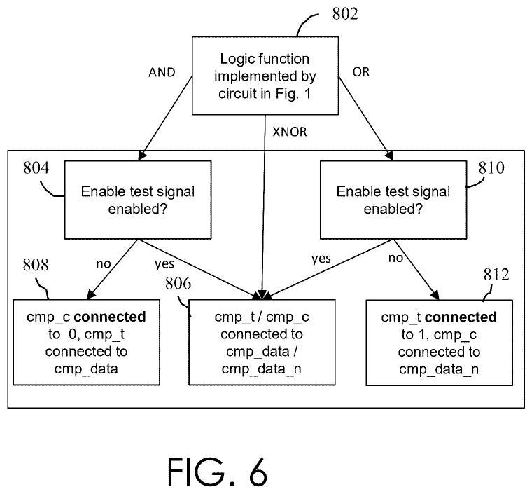

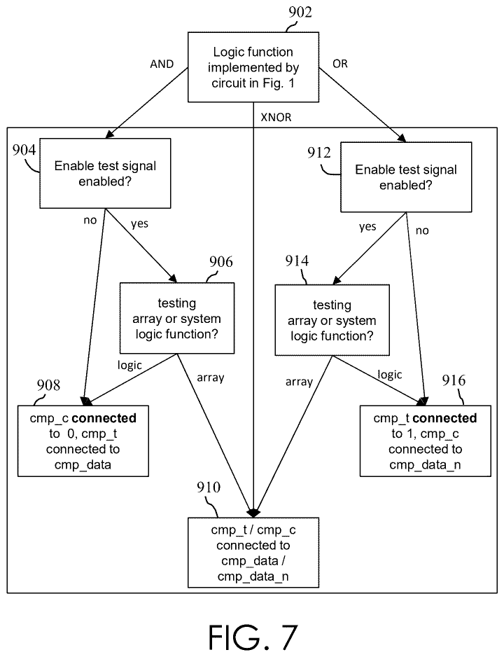

FIG. 5A shows yet another example implementation of a logic gate that provides controllable input for switching the operations of a circuit in some embodiments. A logic gate configuration (also referred to as a second circuit) 502 has a latch, and can be implemented to the test mode signal. Such implementation can avoid timing conflicts such as race conditions. Advantageously, the test mode is multiplexed into the scan input, also allowing to test the latch itself. This implementation uses the functional latch input for functional use of the circuit 100, 130 and scan latch input for self-test (and scan).

This implementation uses a latch 504 to switch between the data input for the system mode and the scan input of the latch 504 for the ABIST signal. An example of the latch 504 is an N1 latch. Other types of latches can be used. When the enable bit 306 is set to one or enabled (during test_ena=1), latch 504 is set to scan mode. Multiplexer 506 receives enable bit 306 as selector input, and control signal from ABIST engine (test_mode) 406 and SCAN_IN signal 508 as data inputs. If enable bit (test_ena) 306 is set to one, multiplexer 506 selects test_mode value (value of 406); if enable bit (test_ena) 306 is set to zero, multiplexer 506 outputs SCAN_IN value (value of 508). Latch 504 receives the output of multiplexer 506 and VSS 510 and multiplexes between the output signal from multiplexer 506 and VSS 510. VSS 510 is a system input to the circuit. The output from latch 504 is used as input to AND 304 gate. This embodiment of the implementation that uses a latch for the control signal from ABIST engine can facilitate correct timing on the signal. Regarding SCAN_IN signal 508, to store values in a signal line in a pipelined operation mode of a processor, latches will hold the value of a logic block per cycle. To test and initiate the latches they are chained together in series. If the processor needs to get initialized all latches get their initial value (after e.g., power on) via scanning a train of 0's and 1's across all latches. Scanning of values is done via a scan input port.

FIG. 5B shows still yet another example implementation of a logic gate that provides controllable input for switching the operations of a circuit in some embodiments. A logic gate configuration (also referred to as a second circuit) 502 has a latch, and can be implemented to the test mode signal. Such implementation can avoid timing conflicts such as race conditions. Advantageously, the test mode is multiplexed into the scan input, also allowing to test the latch itself. This implementation uses the functional latch input for functional use of the circuit 100, 130 and scan latch input for self-test (and scan). This implementation uses a latch 504 to switch between the data input for the system mode and the scan input of the latch 504 for the ABIST signal. When the enable bit 306 is set to one or enabled (during test_ena=1), latch 504 is set to scan mode. Multiplexer 506 receives enable bit 306 as selector input, and control signal from ABIST engine (test_mode) 406 and SCAN_IN signal 508 as data inputs. If enable bit (test_ena) 306 is set to one, multiplexer 506 selects test_mode value (value of 406); if enable bit (test_ena) 306 is set to zero, multiplexer 506 outputs SCAN_IN value (value of 508). Latch 504 receives the output of multiplexer 506 and VSS 510 and multiplexes between the output signal from multiplexer 506 and VSS 510. VSS 510 is a system input to the circuit. The output from latch 504 is used as input to inverter 316 whose output is input to OR gate 314. This embodiment of the implementation that uses a latch for the control signal from ABIST engine can facilitate correct timing on the signal.

In other embodiments, a multiplexer can be implemented, which performs multiplexing based on the select signal of test enable 306 and multiplexing between the zero and the compare values.

FIG. 6 is a flow diagram illustrating a method of switching a circuit to function as one of a plurality of logical gate functions in some embodiments. The flow shows switching the logic function of the true complement dynamic circuit. At 802, given a circuit of configuration shown in FIG. 1, which has capabilities to act as one of XNOR, AND and OR gates, an enable bit or signal controls what operation the circuit performs. At 804, the circuit can operate as an AND gate or operate as an XNOR gate based on the value of test enable signal. Test enable signal is also referred to as enable test signal. For example, at 806, an enabled test signal (that is, enable test signal set to one) causes compare true (CMP_T) and compare complement (CMP_C) bit lines of the circuit to connect to compare data (cmp_data) and compare data complement (cmp_data_n), causing the circuit to operate as XNOR gate. At 808, when enable test signal is not enabled, that is, enable test signal is zero, compare complement (CMP_C) bit line of the circuit connects to zero, compare true (CMP_T) bit line connects to compare data (cmp_data), causing the circuit to operate as an AND gate.

Similarly at 810, based on enable test signal, the circuit can operate as an OR gate or XNOR gate. As described above, at 806, an enabled test signal (that is, enable test signal set to one) causes compare true (CMP_T) and compare complement (CMP_C) bit lines of the circuit to connect to compare data (cmp_data) and compare data complement (inverted compare data referred to as cmp_data_n), causing the circuit to operate as XNOR gate. At 812, when enable test signal is not enabled, that is, enable test signal is zero, compare true (CMP_T) bit line of the circuit connects to one, compare complement (CMP_C) bit line of the circuit connects compare data complement (inverted compare data referred to as cmp_data_n), causing the circuit to operate as an OR gate.

FIG. 7 is a flow diagram illustrating a method of switching circuit functions based on desired operations in some embodiments. The flow shows switching logic function of true complement dynamic circuit for improving testability. This implementation allows an external engine such as ABIST engine to test both, the array content (e.g., test pattern) or the logic function (e.g., with a special test pattern). Different test patterns including a wide range of input signals can be used to test the functionality of the circuit. In this flow, the circuit at 902 can be used in system data usage mode or test mode. In test mode, the circuit can be used to test a logic function as well as a memory array. At 904, enabling enable test signal (e.g., enable test signal set to one) allows to select between memory array testing or an AND logic function testing at 906. For testing an AND logic function, at 908, compare complement (CMP_C) bit line of the circuit connects to zero, compare true (CMP_T) bit line connects to compare data (cmp_data), causing the circuit to operate as an AND gate. For testing a memory array, at 910, compare true (CMP_T) and compare complement (CMP_C) bit lines of the circuit to connect to compare data (cmp_data) and compare data complement (cmp_data_n), causing the circuit to operate as XNOR gate.

At 904, when enable test signal is not set or deactivated (e.g., enable test signal set to zero), at 908, compare complement (CMP_C) bit line of the circuit connects to zero, compare true (CMP_T) bit line connects to compare data (cmp_data), causing the circuit to operate as an AND gate.

Similarly, at 912, an enable test signal being set to one allows to select between memory array testing or an OR logic function testing at 914. For testing an OR logic function, at 916, compare true (CMP_T) bit line of the circuit connects to one, compare complement (CMP_C) bit line of the circuit connects compare data complement (inverted compare data referred to as cmp_data_n), causing the circuit to operate as an OR gate. For testing a memory array, at 910, compare true (CMP_T) and compare complement (CMP_C) bit lines of the circuit to connect to compare data (cmp_data) and compare data complement (cmp_data_n), causing the circuit to operate as XNOR gate.

At 912, when enable test signal is not set (e.g., enable signal set to zero), at 916, compare true (CMP_T) bit line of the circuit connects to one, compare complement (CMP_C) bit line of the circuit connects compare data complement (inverted compare data referred to as cmp_data_n), causing the circuit to operate as an OR gate.

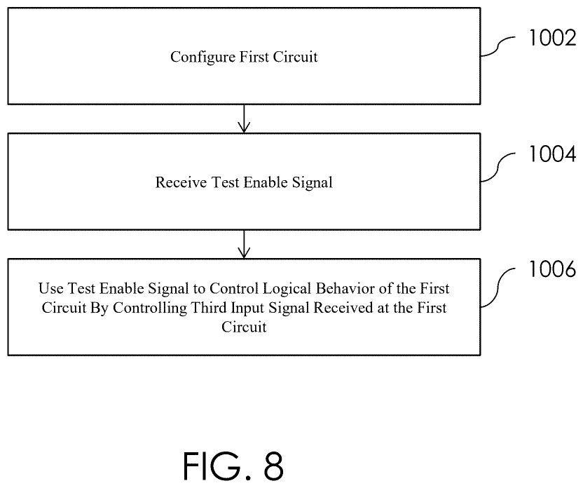

FIG. 8 is another diagram illustrating a method in some embodiments, for flexibly switching a circuit's behavior in some embodiments. At 1002, a first circuit is configured to perform a Boolean logic. As described above, for example, with reference to FIG. 1 at 100, the first circuit is configured to receive, via bit lines, a first input signal and a second input signal. The first input signal and the second input signal are dynamic signals, and are complementary signals (to one another) during an evaluation phase. For example, the first input signal is a signal received at RBL_T 80, shown in the figures described herein; the second input signal is a signal received at RBL_C 82, shown in the figures described herein. The first circuit is further configured to receive a third input signal and a fourth input signal via data lines. For example, the third input signal is a signal received at CMP_C 84, shown in the figures described herein; the fourth input signal is a signal received at CMP_T 86, shown in the figures described herein.

At 1004, a second circuit receives a test enable signal, such as an enable array built-in self-test signal, e.g., referred to above as test_ena (e.g., shown as 306). As described above, for example, a second circuit or additional circuit is configured to control the logical behavior of the first circuit. Examples of second circuit are shown at 302 in FIGS. 3A, 402 in FIG. 4A, and the second circuit 502 in FIG. 5A.

At 1006, using the enable array built-in self-test signal, the second circuit controls the logical behavior of the first circuit by controlling the third input signal received at the first circuit, for example, as described above.

For example, responsive to the enable test signal being set (e.g., test_ena=1), the second circuit outputs inverted compare data as the third input signal that is received by the first circuit (e.g., via complement compare data line), where the inverted compare data as the third input signal received by the first circuit (e.g., via the complement compare data line) causes the first circuit to behave as an XNOR gate, e.g., perform an XNOR logic.

Responsive to the enable test signal being deactivated (e.g., test_enable=0), the second circuit outputs a value of zero as the third input signal that is received by the first circuit (e.g., via the complement compare data line), where the zero value as the third input signal received by the first circuit causes the first circuit to perform an AND logic, e.g., behave as an AND gate.

In some embodiments, the second circuit is configured with an AND gate. This AND gate receives as input the enable array built-in self-test signal and an inverted value of compare data, where an output of the AND gate is fed as the third input signal to the first circuit (e.g., via the complement compare data line).

In some embodiments, a multiplexer configured on the second circuit, based on the enable array built-in self-test signal as a selector input of the multiplexer, multiplexes signals between a control signal from an external engine external to the second circuit and ground level voltage. The second circuit uses output of the multiplexer to control the logical behavior of the first circuit.

In some embodiments, a latch configured on the second circuit receives a control signal from an external engine external to the second circuit and ground level voltage. The second circuit uses output of the latch to control the logical behavior of the first circuit.

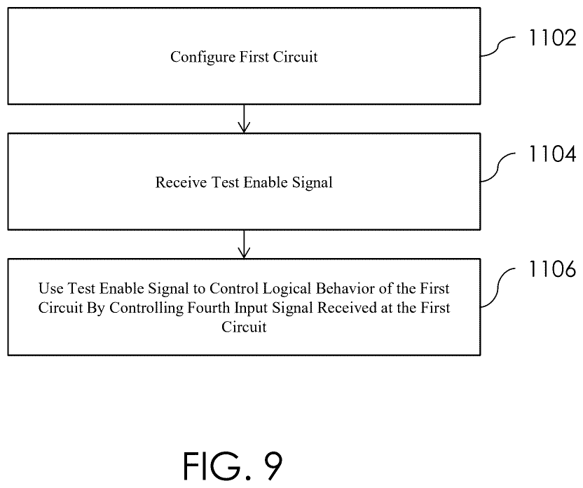

FIG. 9 is another diagram illustrating a method in some embodiments, for flexibly switching a circuit's behavior in some embodiments. At 1102, a first circuit is configured to perform a Boolean logic. As described above, for example, with reference to FIG. 1 at 100, the first circuit is configured to receive, via bit lines, a first input signal and a second input signal. The first input signal and the second input signal are dynamic signals and are complementary signals (to one another) during an evaluation phase. For example, the first input signal is a signal received at RBL_T 80, shown in the figures described herein; the second input signal is a signal received at RBL_C 82, shown in the figures described herein. The first circuit is further configured to receive a third input signal and a fourth input signal via data lines. For example, the third input signal is a signal received at CMP_C 84, shown in the figures described herein; the fourth input signal is a signal received at CMP_T 86, shown in the figures described herein.

At 1104, a second circuit receives a test enable signal, such as an enable array built-in self-test signal, e.g., referred to above as test_ena (e.g., shown as 306). As described above, for example, a second circuit or additional circuit is configured to control the logical behavior of the first circuit. Examples of second circuit are shown at 312 in FIG. 3B, the circuit 410 in FIG. 4B, and circuit 512 in FIG. 5B.

At 1106, using the enable array built-in self-test signal, the second circuit controls the logical behavior of the first circuit by controlling the fourth input signal received at the first circuit, for example, as described above.

Responsive to the enable test signal being set to enabled (e.g., test_ena=1), the second circuit outputs compare data as the fourth input signal received by the first circuit (e.g., via the true compare data line, CMP_T), where the compare data as the fourth input signal received by the first circuit (e.g., via the true compare data line, CMP_T of the first circuit) causes the first circuit to perform an XNOR logic, e.g., behave as an XNOR gate.

Responsive to the enable test signal being set deactivate (e.g., test_ena=0), the second circuit outputs a value of one as the fourth input signal received by the first circuit (e.g., via the true compare data line, CMP_T) where the value of one (‘1’) as the fourth input signal received by the first circuit causes the first circuit to perform an OR logic, e.g., behave as an OR gate.

In some embodiments, the second circuit is configured with an OR gate. This OR gate receives as input an inverted value of the enable array built-in self-test signal and compare data, where an output of the OR gate is fed as the fourth input signal to the first circuit (e.g., true compare data line CMP_T on the first circuit).

The techniques disclosed herein also can work with variations in configurations of the first circuit (e.g., shown in FIG. 1 at 100). For example, the polarity of circuit 100 can be changed, or power rails can be exchanged, e.g., by replacing NFET and PFET transistors with their counterparts. Cross coupled NAND gate (FIG. 1 at 60) can be replaced by a cross coupled NOR gate, and the reset state obtained by clocking the cross coupled gate with the non-inverted clock.

For instance, with reference to the first circuit (e.g., shown in FIG. 1 at 100), by preserving the overall structure of the first circuit, the implementation can be realized by inverting the logic of the first circuit. For example, the 2-input cross-coupled NAND (FIG. 1 at 60) can be replaced by a 2-input cross-coupled NOR gate. The inverted active clock LCK_N to reset the state of the cross-coupled NAND can be replaced by a non-inverted clock LCK to reset the state of the cross-coupled NOR gate. The circuitry in front of the 2-input cross-coupled NOR gate can exchange all NFET devices with PFET devices and vice versa. The power levels VSS and VDD can be exchanged. These changes in the configuration of the first circuit alters the dynamic logic, since the precharge device and keeper device will be changed from PFETs connected to VDD to NFETs connected to VSS/GND. Thus precharge will result in a logic 0 on the true and complement read bit lines (RBL_T and RBL_C), i.e., RBL_T and RBL_C are precharged to 0 instead of 1. A true complement dynamic circuit (e.g., a circuit for comparing binary data on dynamic first and second input signals 80, 82 to third and fourth input signals 84, 86) with such variations can represent an XOR gate as a precharge to ‘0’ logic circuit. Even with variations of the first circuit, the second circuit can be connected to the first circuit in a similar manner described herein to allow full testability of the read bit lines and the first circuit. In some embodiments, the first circuit can have one or more variations in configurations described in U.S. Pat. No. 11,881,583, entitled “TRUE COMPLEMENT DYNAMIC CIRCUIT AND METHOD OF COMBINING BINARY DATA”.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in some embodiments” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A device comprising:
a first circuit configured to perform a Boolean logic, the first circuit configured to receive via bit lines, a first input signal and a second input signal, wherein the first input signal and the second input signal are dynamic signals that are complementary signals during an evaluation phase, the first circuit further configured to receive a third input signal and a fourth input signal via data lines; and
a second circuit connected to the first circuit and configured to control a logical behavior of the first circuit by controlling at least one of: the third input signal and the fourth input signal, received at the first circuit.

2. The device of claim 1, wherein the second circuit is configured to control the logical behavior of the first circuit based on receiving an enable test signal as an input to a logic gate of the second circuit to enable full testability of the first circuit.

3. The device of claim 2, wherein the enable test signal being enabled causes the second circuit to output inverted compare data as the third input signal that is received by the first circuit, wherein the inverted compare data as the third input signal received by the first circuit causes the first circuit to perform an XNOR logic, wherein the third input signal and the fourth input signal received by the first circuit are complementary signals.

4. The device of claim 2, wherein the enable test signal being deactivated causes the second circuit to output a value of zero as the third input signal that is received by the first circuit, wherein the zero value as the third input signal received by the first circuit causes the first circuit to perform an AND logic.

5. The device of claim 2, wherein the enable test signal being enabled causes the second circuit to output compare data as the fourth input signal received by the first circuit, wherein the compare data as the fourth input signal received by the first circuit causes the first circuit to perform an XNOR logic, wherein the third input signal and the fourth input signal received by the first circuit are complementary signals.

6. The device of claim 2, wherein the enable test signal being deactivated causes the second circuit to output a value of one as the fourth input signal received by the first circuit, wherein the value of one as the fourth input signal received by the first circuit causes the first circuit to perform an OR logic.

7. The device of claim 2, wherein the second circuit includes an AND gate configured to receive as input the enable test signal and an inverted value of compare data, wherein an output of the AND gate is fed as the third input signal to the first circuit.

8. The device of claim 2, wherein the second circuit includes an OR gate configured to receive as input an inverted value of the enable test signal and compare data, wherein an output of the OR gate is fed as the fourth input signal to the first circuit.

9. The device of claim 2, wherein the second circuit is further configured with a multiplexer that multiplexes between a control signal from an external engine external to the second circuit and ground level voltage, and generates output based on the enable test signal as a selector input of the multiplexer, the second circuit using the output of the multiplexer to control the logical behavior of the first circuit.

10. The device of claim 2, wherein the second circuit is further configured with a latch receiving as input a control signal from an external engine external to the second circuit and ground level voltage, the second circuit using output of the latch to control the logical behavior of the first circuit.

11. A method comprising:
configuring a first circuit to perform a Boolean logic, the first circuit configured to receive via bit lines, a first input signal and a second input signal, wherein the first input signal and the second input signal are dynamic signals that are complementary signals during an evaluation phase, the first circuit further configured to receive a third input signal and a fourth input signal via data lines;
receiving, by a second circuit, an enable test signal as an input to the second circuit; and
using the enable test signal, controlling, by the second circuit, a logical behavior of the first circuit by controlling the third input signal received at the first circuit.

12. The method of claim 11, further comprising:
responsive to the enable test signal being set to enabled, outputting by the second circuit, inverted compare data as the third input signal that is received by the first circuit, wherein the inverted compare data as the third input signal received by the first circuit causes the first circuit to perform an XNOR logic, wherein the third input signal and the fourth input signal received by the first circuit are complementary signals.

13. The method of claim 11, further comprising:
responsive to the enable test signal being deactivated, outputting by the second circuit, a value of zero as the third input signal that is received by the first circuit, wherein the zero value as the third input signal received by the first circuit causes the first circuit to perform an AND logic.

14. The method of claim 11, wherein the second circuit is configured with an AND gate, the AND gate receiving as input the enable test signal and an inverted value of compare data, wherein an output of the AND gate is fed as the third input signal to the first circuit.

15. The method of claim 11, further comprising:
multiplexing by a multiplexer configured on the second circuit, based on the enable test signal as a selector input of the multiplexer, signals between a control signal from an external engine external to the second circuit and ground level voltage; and
using, by the second circuit, output of the multiplexer to control the logical behavior of the first circuit.

16. The method of claim 11, further comprising:
receiving by a latch configured on the second circuit, a control signal from an external engine external to the second circuit and ground level voltage; and
using, by the second circuit, output of the latch to control the logical behavior of the first circuit.

17. A method comprising:
configuring a first circuit to perform a Boolean logic, the first circuit configured to receive via bit lines, a first input signal and a second input signal, wherein the first input signal and the second input signal are dynamic signals that are complementary signals during an evaluation phase, the first circuit further configured to receive a third input signal and a fourth input signal via data lines;
receiving, by a second circuit, an enable test signal; and
using the enable test signal, controlling, by the second circuit, a logical behavior of the first circuit by controlling the fourth input signal received at the first circuit.

18. The method of claim 17, further comprising:
responsive to the enable test signal being set to enabled, outputting by the second circuit, compare data as the fourth input signal received by the first circuit, wherein the compare data as the fourth input signal received by the first circuit causes the first circuit to perform an XNOR logic.

19. The method of claim 17, further comprising:
responsive to the enable test signal being deactivated, outputting by the second circuit, a value of one as the fourth input signal received by the first circuit, wherein the value of one as the fourth input signal received by the first circuit causes the first circuit to perform an OR logic.

20. The method of claim 17, wherein the second circuit is configured with an OR gate, the OR gate receiving as input an inverted value of the enable test signal and compare data, wherein an output of the OR gate is fed as the fourth input signal to the first circuit.
